(19) United States
(12) Patent Application Publication
(10) Pub. No.: US 2024/0227210 A1
(43) Pub. Date: Jul. 11, 2024

(54) BLADE-TYPE END EFFECTOR WITH ANGULAR COMPLIANCE MECHANISM

(71) Applicant: Lam Research Corporation, Fremont, CA (US)

(72) Inventors: Ross C. Embertson, West Linn, OR (US); Brandon Lee Senn, Molalla, OR (US); Charles N. Ditmore, Oakland, CA (US)

(21) Appl. No.: 18/560,334

(22) PCT Filed: May 11, 2022
(86) PCT No.: PCT/US2022/028857

§ 371 Date: Nov. 10, 2023

Related U.S. Application Data
(60) Provisional application No. 63/201,842, filed on May 14, 2021.

(51) Int. Cl. B25J 15/08; B25J 17/02

(52) U.S. Cl. CPC B25J 15/08; B25J 17/02

(57) ABSTRACT

Disclosed herein are wafer handling robots and related systems for providing a blade-type end effector that has a built-in compliance mechanism that allows the end effector blades to rotate by a small amount relative to a wrist unit housing of the end effector wrist unit due to gravitational loading in both a first configuration and a second configuration in which the wrist unit housing is flipped upside down from the first configuration. Such a system may be used in conjunction with end effector blades made of high-stiffness materials such as silicon carbide, allowing such end effector blades to be used in conditions that normally require end effector blades made of more compliant materials.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Wafer handling robots may use a variety of different types of end effectors to handle semiconductor wafers. Such end effectors may include, for example, blade-type end effectors that are typically long, thin metal spatula-like structures that are designed to support semiconductor wafers from beneath. Such end effectors are typically quite thin, e.g., on the order of only a few mm in thickness so as to be able slip between wafers that are arranged in a vertical stack with 10 mm of center-to-center spacing between wafers.

Disclosed herein are improvements to wafer handling robots with blade-type end-effectors.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes an end effector wrist unit. The end effector wrist unit may include a wrist unit housing, an end effector mount assembly having a first end effector mount, and one or more rotational interfaces. The first end effector mount may be configured to mechanically connect with a first end effector blade having a major surface defining a first plane, the end effector mount assembly may be connected with the wrist unit housing via the one or more rotational interfaces such that the end effector mount assembly is rotatable through a first angular range of motion relative to the wrist unit housing and about a first axis, and the first axis may be substantially parallel to the first plane when the first end effector is mounted to the first end effector mount.

In some implementations, the first end effector mount may have a first planar end effector mounting surface that is configured to mate against the first end effector blade when the first end effector mount is mated to the first end effector blade and the first planar end effector mounting surface is parallel to the first axis.

In some implementations, the apparatus may further include the first end effector blade.

In some implementations, the apparatus may comprising a first positive stop and a second positive stop, the first positive stop positioned so as to contact a portion of the end effector mount assembly when the end effector mount assembly is at a first rotational limit of the first angular range of motion and the second positive stop positioned so as to contact a portion of the end effector mount assembly when the end effector mount assembly is at a second rotational limit of the first angular range of motion.

In some such implementations, one or both of the first positive stop and the second positive stop may be adjustable.

In some implementations, the first angular range of motion may be less than 10 degrees.

In some implementations, the apparatus may further include a damper mechanism that is configured to damp rotational movement of the end effector mount assembly relative to the wrist unit housing.

In some implementations, the apparatus may further include a draw link and a rocker arm. The draw link may have a first end rotatably coupled to a first end of the rocker arm so as to be rotatable about a second axis relative to the rocker arm and a second end rotatably coupled to the end effector mount assembly so as to be rotatable about a third axis relative to the end effector mount assembly. The rocker arm may also have a second end rotatably coupled with a first end of the damper mechanism so as to be rotatable about a fourth axis relative to the damper mechanism and may be mounted so as to be rotatable about a fifth axis that is fixed with respect to the wrist unit housing.

In some implementations, a first distance between the fifth axis and the fourth axis may be greater than a second distance between the fifth axis and the second axis.

In some such implementations, the first distance may be at least 1.5 times the second distance.

In some implementations, the apparatus may further include a second end effector blade that is fixed with respect to the end effector mount assembly.

In some implementations, the first and second end effector blades may each have corresponding distal ends and corresponding proximal ends, the proximal ends of the first and second end effector blades may be fixedly mounted to the end effector mount assembly, the distal ends of the first and second end effector blades may each have a corresponding distal cleat mounted thereto, each distal cleat may have riser portion extending away from the corresponding end effector blade and a catch surface extending outward from the riser portion thereof, and each catch surface may be spaced apart from the corresponding end effector blade by at least a first gap distance.

In some implementations, each catch surface may slope away from the corresponding end effector blade with increasing distance from the riser portion from which that catch surface extends.

In some such implementations, the apparatus may further include an actuator mechanism and a proximal cleat. The actuator mechanism may have a first portion and a second portion, the first portion of the actuator mechanism may be fixed with respect to the end effector mount assembly, the second portion of the actuator mechanism may be configured to be movable between a first configuration and a second configuration relative to the first portion of the actuator mechanism, the proximal cleat may be fixed with respect to the second portion of the actuator mechanism and may have a catch surface that faces in substantially the same direction as the catch surfaces of the distal cleats, the catch surface of the proximal cleat and the catch surfaces of the distal cleats, in the first configuration, may not overlap a first reference circle when the second portion of the actuator mechanism is in the first configuration, the catch surface of the proximal cleat and the catch surfaces of the distal cleats, in the second configuration, may all overlap a second reference circle when the second portion of the actuator mechanism is in the second configuration, and the first reference circle and the second reference circle may have the same diameter.

In some implementations, the first reference circle may have a diameter selected from the group consisting of 200 mm, 300 mm, and 450 mm.

In some implementations, the end effector wrist unit may be configured such that when the end effector wrist unit is positioned in a first orientation with the first axis horizontal and the first plane substantially horizontal, the end effector mount assembly moves to the first rotational limit of the first angular range of motion due solely to gravitational loading, and when the end effector wrist unit is positioned in a second orientation opposite the first orientation, the end effector mount assembly also moves to the second rotational limit of the first angular range of motion due solely to gravitational loading.

In some implementations, the first end effector blade may be made of a ceramic material.

In some such implementations, the first end effector blade may be made of silicon carbide.

In some implementations, the apparatus may further include a base, one or more robot arm links, and a wrist drive unit. The one or more robot arm links may include a first robot arm link that is configured to be rotatable relative to the base and about a base axis, the wrist drive unit may be supported by the one or more robot arm links and may include a wrist mount that is rotatable about an axis that is perpendicular to an axis that is parallel to the base axis, and the end effector wrist unit may be mounted to the wrist mount.

In some implementations, the apparatus may include a base, one or more robot arm links, and a wrist drive unit. The one or more robot arm links may include a first robot arm link that is configured to be rotatable relative to the base, the wrist drive unit may be supported by the one or more robot arm links and may include a wrist mount that is rotatable about an axis that is perpendicular to the first axis, and the end effector wrist unit may be mounted to the wrist mount.

In some implementations, a method may be provided that includes a) moving an end effector wrist unit to a first position relative to a wafer resting on a pedestal, the end effector wrist unit supporting one or more end effector blades that are rotationally mounted with respect to the end effector wrist unit by way of one or more rotational interfaces (the one or more end effector blades may be rotatable about a first axis relative to the end effector wrist unit and the one or more end effector blades may have distal cleats mounted to a distal end or ends thereof), b) lowering the end effector wrist unit from the first position to a second position in which the distal cleats first contact the pedestal, and c) further lowering the end effector wrist unit from the second position to a third position, thereby causing the one or more end effector blades to rotate about the first axis relative to the end effector wrist unit.

In some implementations of the method, when in the third position, a proximal cleat that is supported by the end effector wrist unit may be positioned with a catch surface thereof positioned such that at least part of the catch surface is at a lower elevation than an edge of the wafer with respect to a normal vector of the wafer.

In some implementations of the method, the method may further include moving at least one cleat of the distal cleats and the proximal cleat radially inward with respect to the wafer such that the catch surface of the proximal cleat and catch surfaces of the distal cleats all overlap the wafer when viewed along an axis perpendicular to the wafer.

In some further such implementations, the method may further include raising the end effector wrist unit by a fourth distance after moving the at least one cleat of the distal cleats and the proximal cleat radially inward with respect to the wafer, thereby lifting the wafer off of the pedestal.

In some additional such implementations, the method may further include rotating the end effector wrist unit by 180° about a second axis perpendicular to the first axis and substantially parallel to the wafer after raising the end effector wrist unit by the fourth distance.

In addition to the above-listed implementations, other implementations evident from the discussion below and the Figures are to be understood to also fall within the scope of this disclosure.

### BRIEF DESCRIPTION OF THE FIGURES

Reference to the following Figures is made in the discussion below; the Figures are not intended to be limiting in scope and are simply provided to facilitate the discussion below.

FIG. 1 depicts an isometric view of an example apparatus having a wafer handling robot.

FIGS. 2-1 through 2-3 depict side views of an example end effector wrist unit and end effector blades in various operational states.

FIG. 3 depicts an exploded view of an example end effector wrist unit and end effector blades.

FIG. 4 depicts an isometric view of an example end effector wrist unit and end effector blades.

FIG. 5 depicts the example end effector wrist unit of FIG. 4 but in a different operational configuration.

FIG. 6 depicts a side section view of an example end effector wrist unit.

FIGS. 7-11 depict side views of an example end effector wrist unit and end effector blades during various stages of a wafer pick operation.

### DETAILED DESCRIPTION

One particular type of blade-type end effector that may be used in some semiconductor processing tools may be configured to hold semiconductor wafers both from below and from above. For example, such an end effector may support a semiconductor wafer from below and then be rotated 180° about a wrist axis of the wafer handling robot so that the end effector is now positioned above the semiconductor wafer and the semiconductor wafer is supported by, for example, cleats which may have catch surfaces that overlap the semiconductor wafer when viewed along an axis perpendicular to the semiconductor wafer. Such an end effector may be used to flip wafers 180° (top to bottom or vice-versa) in between some wafer placement operations.

When picking a wafer up with the end effector positioned beneath the wafer, the wafer may be lifted clear of a wafer support of a semiconductor processing chamber by a lift pin mechanism or may be suspended in the air, e.g., via having its outermost edges engaged with a wafer support ledge in a front-opening unified pod (FOUP) or similar structure, such that the end effector can be inserted beneath the wafer and the wafer then lowered onto the end effector or the end effector moved vertically upwards so as to lift the wafer off of the structure that supports it. Once the wafer is resting on the end effector, the end effector may be moved about and the wafer may, if the speed of the end effector is controlled to avoid slippage, move with it.

When picking up a wafer with the end effector positioned above the wafer, a different approach may be pursued. For example, the wafer support or other structure on which the wafer rests may have one or more depressions or recesses around the circumference of the wafer that may align with corresponding distal cleats on the end effector blades. The end effector blades may be angled slightly downward and lowered such that the distal ends of the end effector blades, and thus the distal cleats located thereupon, come into contact with the wafer support or other structure. The end effector wrist unit, to which the proximal ends of the end effector blades may be attached, may then continue to be lowered until a proximal cleat on a side of the wafer opposite the distal cleats (e.g., interposed between the wafer and the end effector wrist unit) is aligned with the wafer edge such that when the proximal cleat is moved radially inward towards the wafer center (and optionally, when the end effector and distal cleats are moved in the opposite direction), the proximal and distal cleats may engage with the wafer and catch surfaces thereof may slide below the wafer edge, thus acting to support the wafer from below. During such further downward movement, the end effector blades, which may be made of titanium or other flexible material, may flex slightly to accommodate the continued downward movement of the end effector relative to the wafer support while the distal cleats remain pressed against the wafer support.

The present inventors determined that in some semiconductor processing tools, however, semiconductor wafers that are processed by the semiconductor processing tool may experience wafer bowing, i.e., due to internal stresses that develop within the wafer during processing, the wafer may warp or bend slightly—in some cases, the wafer may bend sufficiently that the center of the wafer may displace in a direction perpendicular to the wafer plane by, in some cases, nearly as much as the thickness of the wafer. Thus, for example, a 0.775 mm wafer may deflect near the center of the wafer by as much as nearly 0.8 mm. In some cases, there may be even more deflection that the wafer undergoes. As a result, when such wafers are arranged in a vertically stacked arrangement, e.g., with a 10 mm nominal pitch between wafers), the actual minimum distance in between the closest points of adjacent wafers might be as little as ˜7.6 mm as compared to the usual ˜9.2 mm. The present inventors determined that in order to preserve the various clearance tolerances between the end effector and the wafers in the wafer stack, it may be necessary to reduce the thickness of components, e.g., the end effector blade, to preserve those clearance tolerances. However, the present inventors also determined that doing so may make the end effector blades unacceptably thin, i.e., thin to the point where they deflect too much under the weight of a wafer or potentially permanently deform.

To mitigate this issue, the present inventors determined that instead of using a metal material for the end effector blades, e.g., titanium, the end effector blades could instead be made from a material with a higher elastic modulus, e.g., a ceramic such as aluminum nitride, silicon carbide, or aluminum oxide, e.g., in some implementations, materials with a modulus of elasticity of 250 GPa or higher. By using such materials, the end effector blades may be made thinner without necessarily flexing more than is permissible, thereby allowing the clearance tolerances between the end effector and the wafers to be maintained even when the wafers have undergone bowing.

However, the present inventors also determined that using such alternative materials for the end effector blades could prove problematic for end effectors that operate as described above, e.g., with the ability to pick a wafer up from above or below. In particular, end effector blades made of ceramic materials may not be able to flex to the degree that titanium and other metals flex and may thus not be able to accommodate the flexure described above. As a result, such end effector blades may break when the cleats at the distal ends thereof are pushed into the wafer support and cause a bending load to develop within the end effector blades.

To address this issue, the present inventors conceived of an end effector wrist unit in which an end effector mount assembly is able to pivot relative to a wrist unit housing of the end effector wrist unit. For example, the end effector mount assembly may be rotatably coupled with the wrist unit housing using one or more rotational interfaces such that the end effector mount assembly is able to rotate relative to the wrist unit housing about a first axis that is parallel to the plane in which the end effector supports a wafer. Such rotational interfaces may, for example, cooperate with one or more stop structures to permit the end effector mount assembly to undergo such rotation to a very limited degree, e.g., on the order of 10, 9, 8, 7, 6, 5, 4, or 3 degrees or less, e.g., 3 degrees or less.

For example, if the end effector wrist unit is placed in a first orientation with the end effector blades generally parallel to the ground, the end effector mount assembly may rotate into a first position relative to the wrist unit housing due solely to the force of gravity acting on the end effector blades (and potentially aided by the further weight of a wafer). If the same end effector wrist unit is flipped over into a second orientation opposite the first orientation, however, the end effector mount assembly may rotate into a second position relative to the wrist unit housing due solely to the force of gravity acting on the end effector blades (and potentially aided by the further weight of a wafer).

Such a rotational interface may be used to provide a certain amount of compliance between the position of the distal cleats at the distal end of the end effectors and the wrist unit housing, thereby allowing the distal cleats of the end effector to remain in contact with the wafer support—and the end effector blade to avoid bending—while the end effector wrist unit continues to be lowered so that the proximal cleat can be brought into position so as to be engageable with the edge of the wafer.

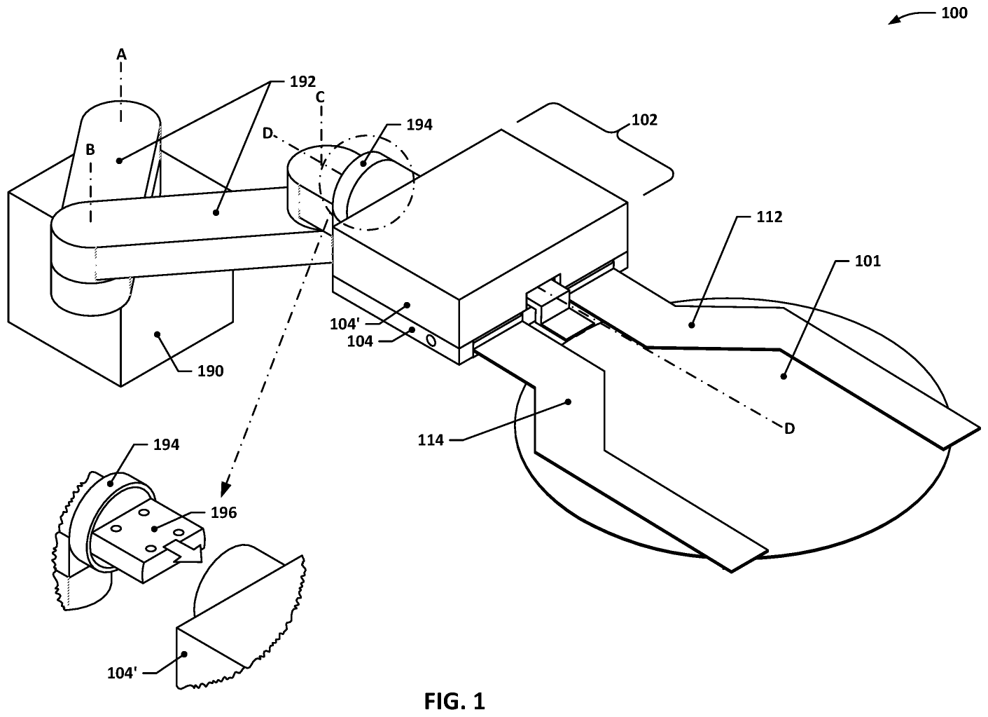

FIG. 1 depicts an example wafer handling robot. In FIG. 1, an apparatus 100, e.g., which may include or be a wafer handling robot, is depicted. The apparatus 100 may include a base 190, one or more robot arm links 192, a wrist drive unit 194, an end effector wrist unit 102, and one or more end effector blades 112/114. Also shown in FIG. 1 is a wafer 101, which may be transported using the wafer handling robot.

The base 190 may include one or more motors and other equipment that may be used to cause other elements of the wafer handling robot to move, e.g., to cause the robot arm links 192 to, for example, rotate relative to the base 190, e.g., so as to cause the entire robot arm, end effector wrist unit 102, and end effector blades 112/114 to rotate about the base 190, and/or rotate relative to the base 190 and each other, e.g., so as to cause the end effector wrist unit 102 to extend radially inward or outward relative to the base 190.

Each robot arm link 192 may be viewed as having a first end and a second end, with the first end rotatably coupled to either the base 190 or another robot arm link 192 and the second end rotatably coupled to either another robot arm link 192 or to the wrist drive unit 194. Each such rotatable connection allows the two elements connected thereby to rotate relative to each other about a rotational axis, such as rotational axes A, B, or C. The wrist drive unit 194 may have a motor or other drive system in it that is configured to impart rotational motion about a rotational axis D to the end effector wrist unit 102. The rotational axis D is perpendicular, for example, to an axis that is parallel to the rotational axes A, B, and/or C.

The wrist drive unit 194 may be controlled so as to cause the end effector wrist unit 102 to be flipped between two orientations 180° apart by rotating the end effector wrist unit 102 about the rotational axis D. It will be appreciated that the wrist drive unit 194 and the end effector wrist unit 102 may also be mounted to other types of robot arm units, e.g., robot arms that are not limited to extension and retraction in a single horizontal plane but which can instead perform more complex movements, e.g., having robot arm links that may rotate about axes other than parallel, vertical axes. Regardless of what type of robot arm the wrist drive unit 194 and the end effector wrist unit 102 are mounted to, the wrist drive unit 194 may be used to cause the end effector wrist unit 102 to flip from a position in which the major surfaces of the end effector blades 112/114 are generally horizontal to a flipped-over position (in which the end effector blades 112/114 are, in effect, upside down or otherwise reversed in orientation).

The end effector wrist unit 102 may include a wrist unit housing 104/104′ that is mounted to the wrist drive unit 194 by way of a wrist mount 196, which is shown withdrawn from the end effector wrist unit 102 in the detail view of FIG. 1. The wrist mount 196 may attach to the wrist unit housing 104/104′ by way of one or more fasteners or other mechanical connections (not shown). The wrist mount 196 may, for example, be rotatable about the rotational axis D relative to the remainder of the wrist drive unit 194.

The end effector wrist unit 102 may have connected thereto a pair of end effector blades 112 and 114; in some implementations, the two end effector blades 112 and 114 may be part of a single, contiguous structure, although in this example they are separate parts. The end effector wrist unit 102 may, it will be understood, be a subassembly of components that connects the end effector blades 112 and 114 to the robot arm assembly that supports the end effector blades 112 and 114.

The end effector blades 112, 114 may be connected with an end effector mount assembly within the end effector wrist unit 102 (discussed in more detail later) that is able to pivot somewhat about an axis that is, for example, perpendicular to axes that are parallel to rotational axes A-D.

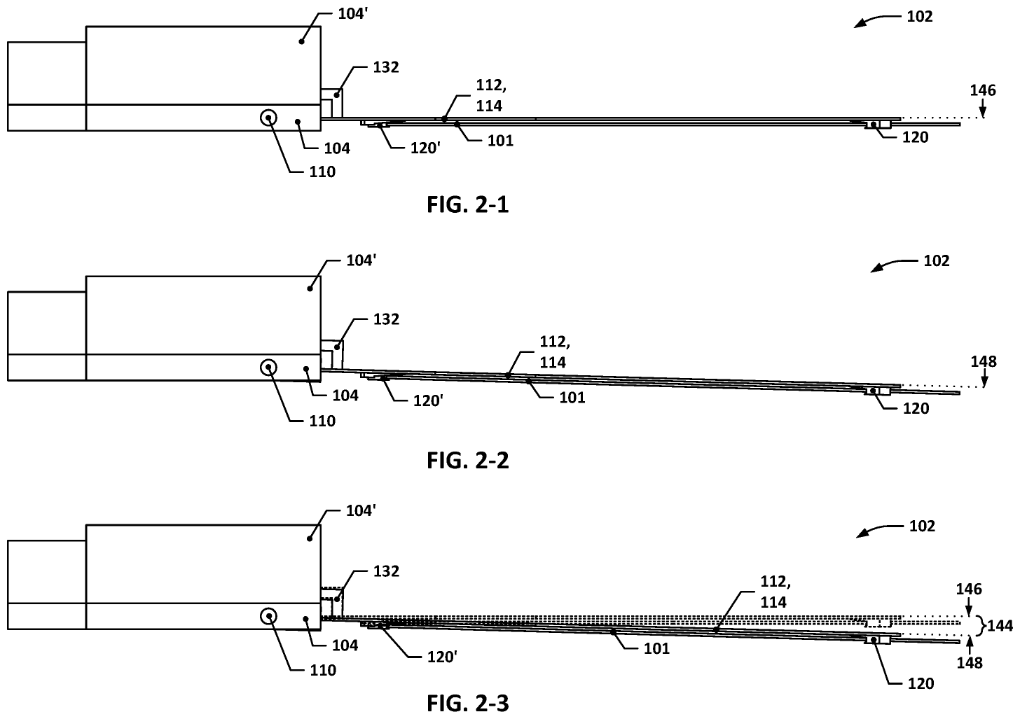

FIGS. 2-1 through 2-3 depict a side view of the end effector wrist unit 102, the end effector blades 112 and 114, and the wafer 101 in various potential pivot positions of the end effector mount assembly (and thus the end effector blades 112, 114 attached thereto). In FIG. 2-1, the wrist unit housing 104, 104′ is shown with a rotational interface 110 visible. The rotational interface 110 may rotatably connect an end effector mount assembly housed in the end effector wrist unit 102 with the wrist unit housing 104. The end effector blades 112, 114, may extend out from the wrist unit housing 104, 104′ and may have, for example, distal cleats 120 and a proximal cleat 120′ that is mounted to an actuator mechanism 132 and which may be used to grip the wafer 101 in the orientation shown. In some implementations, at least one of the distal cleats 120 may affixed to a distal end of the end effector, i.e., stationary with respect to that end effector. In some implementations, the proximal cleat 120′ may be movably mounted to the actuator mechanism 132, e.g., mounted to the movable portion of the actuator mechanism so as to be movable relative to a portion of the actuator mechanism that is fixed with respect to the end effector mount assembly.

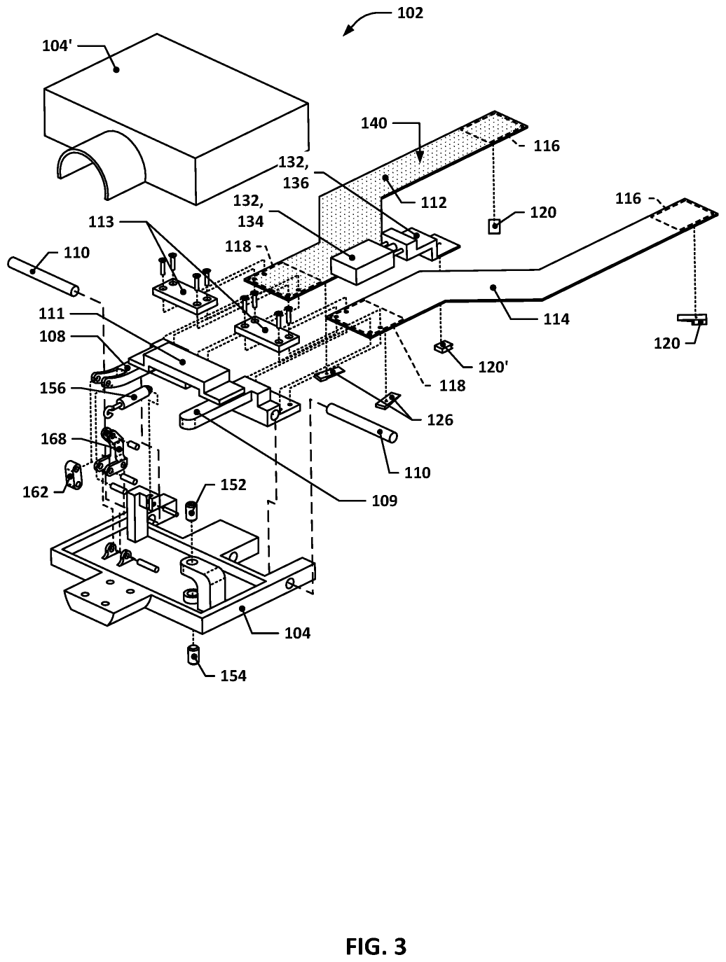

In FIG. 2-1, the end effector mount assembly has been rotated to a first rotational limit 146. In FIG. 2-2, the end effector mount assembly has been rotated to a second rotational limit 148. In FIG. 2-3, FIGS. 2-1 and 2-2 are shown superimposed, with FIG. 2-1 shown in dotted lines, to illustrate the full angular range 144 that the end effector blades 112 and 114 may be swung through rotation of the end effector mount assembly about the rotational interface 110. As can be seen, the amount of angular rotation supported by the rotational interface 110 and other elements of the end effector wrist unit 102 may be quite limited, e.g., on the order of 10° or less, e.g., 3º or less.

FIG. 3 depicts an exploded view of the example end effector wrist unit 102 and the end effector blades 112 and 114 mounted thereto. As can be seen the wrist unit housing 104 and 104′ may house within them a number of components, including an end effector mount assembly that includes a first end effector mount 108, a second end effector mount 109, a bridge structure 111, and clamping plates 113. The clamping plates 113 may be used, in conjunction with the depicted fasteners, to clamp the end effector blades 112, 114, in place relative to the end effector mount assembly.

The bridge structure 111 may span between the first end effector mount 108 and the second end effector mount 109, thereby causing the bridge structure 111, the first end effector mount 108, and the second end effector mount 109 to rotate in unison about the rotational axes of the rotational interfaces 110 when subjected to a torque. The bridge structure 111, the first end effector mount 108, and the second end effector mount 109 may, it will be appreciated, be provided by a single, contiguous structure or by multiple smaller structures joined together in a generally rigid assembly.

The end effector wrist unit 102 in this example includes a damper mechanism 156, e.g., a linear damper mechanism such as a pneumatic damper mechanism, that may be used to damp the rotational movement of the end effector mount assembly about the rotational interface 110's rotational axis.

In this example, the first end effector mount 108 includes an arm portion that extends towards the back of the wrist unit housing 104, e.g., towards where the end effector wrist unit 102 would mount to the wrist mount 196. The arm portion of the first end effector mount 108 may include features to facilitate the afore-mentioned damping functionality. For example, the end effector wrist unit 102 may include a rocker arm 168 and a draw link 162 which may be rotatably coupled with each other and with other components so as to form a linkage that may be used to convert rotational movement of the end effector mount assembly relative to the wrist unit housing 104 to linear movement that can be damped by the damper mechanism 156. This is discussed in further detail below.

The example of FIG. 3 also includes a first positive stop 152 and a second positive stop 154. In this example, the first positive stop 152 and the second positive stop 154 are both set screws that may be screwed in or out of their respective threaded holes so as to adjust the angular range through which the end effector mount assembly can swing or rotate. In other implementations, one or both of the first positive stop 152 and the second positive stop 154 may be fixed, i.e., non-adjustable. For example, the second positive stop 154 may be fixed in position/non-adjustable, while the first positive stop 152 may be adjustable. The second end effector mount 109 may have an arm portion that extends into a gap that exists between the first positive stop 152 and the second positive stop 154; by screwing the first positive stop 152 and/or the second positive stop 154 into/out of their respective threaded holes, the gap distance between the first positive stop 152 and the second positive stop 154 may be adjusted, thus allowing the angular range through which the second end effector mount 109 can swing to be adjusted.

The bridge structure 111 may be used, as noted above, to link the first end effector mount 108 and the second end effector mount 109 together such that they move in unison. The bridge structure may also, in some examples, serve to support the actuator mechanism 132, which may be used to engage or disengage the proximal cleat 120′ from a wafer 101.

The end effector blades 112 and 114 may generally be large, flat structures with a major surface 140 that defines a first plane; the major surface 140 may generally be parallel to a wafer 101 that is to be supported by the end effector blades 112 and 114. The end effector blades 112 and 114 may generally be of similar design, e.g., mirror images of each other, for example. The end effector blades 112 and 114 may, for example, each have proximal ends 118 and distal ends 116. The end effector blades 112 and 114 may be connected with the end effector mount assembly at the proximal ends 118, e.g., by clamping the end effector blades 112 and 114 in between the clamping plates 113 and the first and second end effector mounts 108 and 109, respectively. Distal cleats 120 may be provided at the distal ends 116 of the end effector blades 112 and 114 and connected to the end effector blades 112 and 114 such that they are fixed with respect thereto. The end effector blades 112 and 114 may also have contact pads 126 that may be affixed to the end effector blades 112 and 114 close to the proximal ends 118.

The actuator mechanism 132 may have a first portion 134 that may be mounted, e.g., to the bridge structure 111, so as to be fixed in space with respect to the end effector mount assembly 106 and a second portion 136 that may be movable with respect to the first portion, e.g., able to be extended or retracted along an axis. The proximal cleat 120′ may be mounted to the second portion 136 of the actuator mechanism 132 such that the proximal cleat 120′ can be moved towards or away from the distal ends 116 of the end effector blades 112 and 114.

It will be understood as well that in other additional or alternative implementations, the end effector blades 112 and 114 may be mounted to the end effector mount assembly 106 with an actuator mechanism or mechanisms similar to the actuator mechanism 132, i.e., such that the end effector blades 112 and 114 may be extended or retracted along an axis parallel to an axis perpendicular to the first axis 176 by actuation of the actuator mechanism(s) so as to cause a second portion or portions thereof (to which the end effector blades 112 and 114 may be mounted) to translate along such an axis relative to a first portion or portions thereof (which may be mounted to or part of, for example, the end effector mount assembly 106). In such implementations, the clamps 113 (or other suitable device for affixing the end effector blades 112 and 114 to the end effector wrist unit 102) may instead clamp the end effector blades 112 and 114 to the second portion(s) of the actuation mechanism(s) used to move the end effector blades 112 and 114. In such implementations, the distal cleats may be both pivotable about the first axis and translatable along the axis parallel to an axis perpendicular to the first axis relative to the end effector wrist unit 102. The proximal cleat or cleats may also be translatable along such an axis if the actuator mechanism 132 is retained or may be fixed with respect to the end effector mount assembly 106 if the actuator mechanism 132 is omitted.

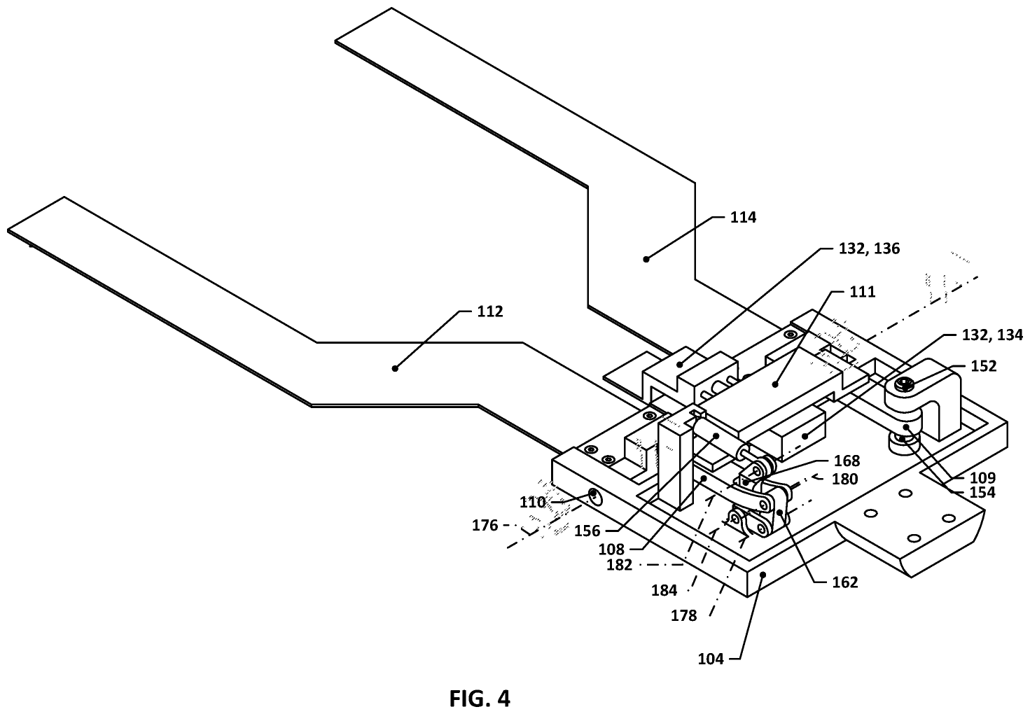

FIG. 4 shows the same assembly from an alternate perspective and in a non-exploded state (with the wrist unit housing 104′ hidden from view). As can be seen, the rotational interfaces 110 allow the end effector mount to rotate about a first axis 176. The rotational interfaces 110, while shown as axles or pins in this example, may be provided using any appropriate rotational mechanism, including, for example, rotational flexure bearings, which may provide a small amount of rotational motion without undergoing or producing any rolling or sliding contact between mating surfaces (thereby reducing the risk of particulate generation).

Also visible in FIG. 4 is the placement of the arm portion of the second end effector mount 109 in between the first positive stop 152 and the second positive stop 154, as well as the assembled linkage that includes the rocker arm 168 and the draw link 162. In addition to the first axis 176, FIG. 4 also depicts a second axis 178, a third axis 180, a fourth axis 182, and a fifth axis 184. As shown, the rocker arm 168 is configured to pivot relative to the wrist unit housing 104 about the fifth axis 184 and is rotatably connected with a first end of the damper mechanism 156 such that the rocker arm 168 can rotate relative to the damper mechanism 156 about the fourth axis 182. The draw link 162, in turn, may be rotatably coupled with the rocker arm 168 so as to be able to rotate relative to the rocker arm 168 about the second axis 178 and is rotatably coupled at the other end with the first end effector mount 108 so as to be able to rotate about a third axis 180 relative to the first end effector mount 108.

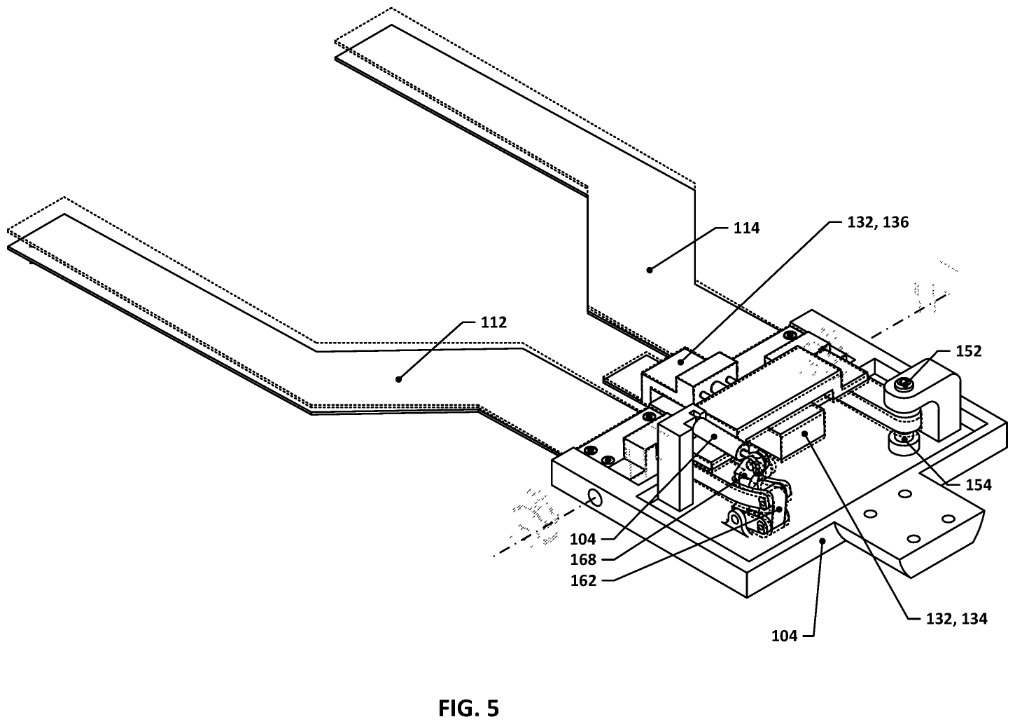

FIG. 5 depicts the same view of FIG. 4, but with the end effector mount assembly rotated to the second rotational limit 148 (the position of the various components as shown in FIG. 4, e.g., at the first rotational limit 146, is shown in dotted lines in FIG. 5). The linkage may be used to increase the linear travel distance experienced by the damper mechanism in response to an amount of vertical travel of the arm portion of the first end effector mount 108, thereby allowing for finer damping control.

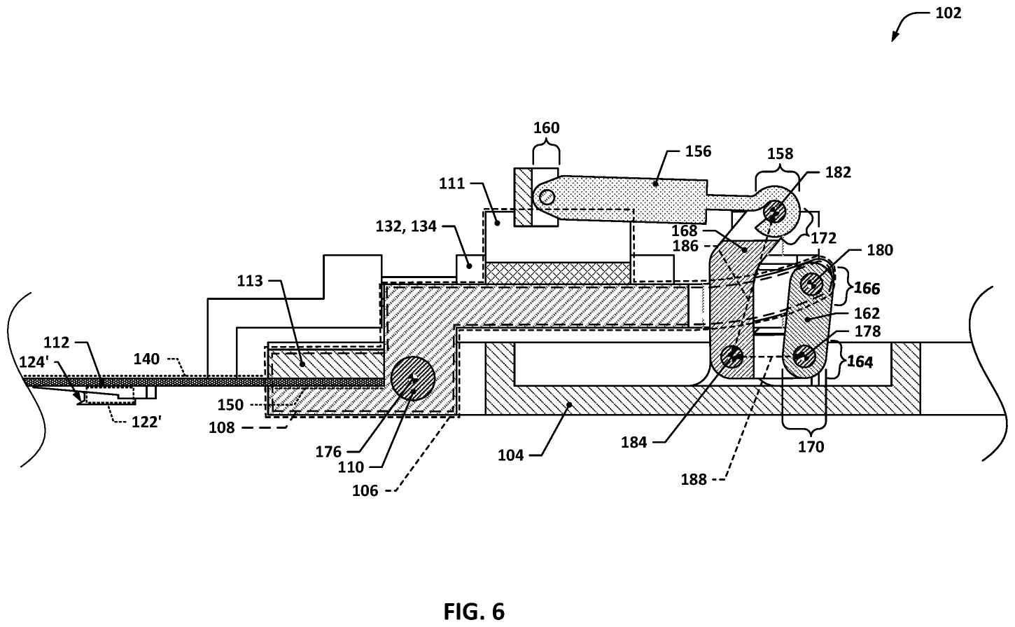

FIG. 6 depicts a side section view of the end effector wrist unit 102, showing the linkage mechanism discussed above in more detail. As can be seen, the end effector mount assembly 106 includes both the first end effector mount 108 and the bridge structure 111. The damper mechanism 156 (shown in profile with internal details omitted) has a first end 158 that is rotatably connected with a second end 172 of the rocker arm 168 such that the two components can rotate relative to each other about the fourth axis 182. The damper mechanism 156 also has a second end 160 that is rotatably connected with the wrist unit housing 104 (or a point fixed in space with respect thereto). In other implementations, the damper mechanism 156 may be rigidly connected with the wrist unit housing 104 and compliance built into other components of the damper mechanism 156 may be used to accommodate the slight rotational movement of the first end 158. The rocker arm 168 has a first end 170 that is rotatably connected with a first end 164 of the draw link 162 such that the two components can rotate relative to each other about the second axis 178 and is rotatably connected with the wrist unit housing 104 by way of a pivot that allows the rocker arm 168 to rotate about the fifth axis 184 relative to the wrist unit housing 104.

The first end effector mount 108 may be rotatably connected at one end with the second end 166 of the draw link 162 such that the draw link 162 is able to rotate relative to the first end effector mount 108 about the third axis 180. When the first end effector mount 108 rotates about the first axis 176 in a clockwise manner, the draw link 162 will be pushed down, causing the rocker arm 168 to rotate clockwise as well. When the first end effector mount 108 rotates about the first axis 176 in a counterclockwise manner, the draw link 162 will be pulled up, causing the rocker arm 168 to rotate counterclockwise. Due to the differing distances between the second axis 178 and the fifth axis 184 and the fifth axis 184 and the fourth axis 182, the rocker arm 168 may act to multiply the damping effects that are applied to the first end effector mount 108 by the damper mechanism 156. For example, the rocker arm may have a first distance 186 between the fourth axis 182 and the fifth axis 184 and a second distance 188 between the fifth axis 184 and the second axis 178 that is smaller than the first distance. In some such implementations, the first distance 186 may be at least 1.5 times, e.g., at least 3 times, at least 3.4 times, at least 3.8 times, or at least 4.2 times the second distance 188.

Also visible in FIG. 6 is a portion of the first end effector blade 112, including a dotted line indicating the major surface 140 of the first end effector blade 112. In this example, the first end effector blade 112 clamps against a first planar end effector mounting surface 150 and is held in place by the clamping plate 113. The first planar end effector mounting surface 150 may, for example, be parallel to the first axis 176. However, it will be understood that other mounting arrangements for the first end effector blade 112 may be used as well, as appropriate.

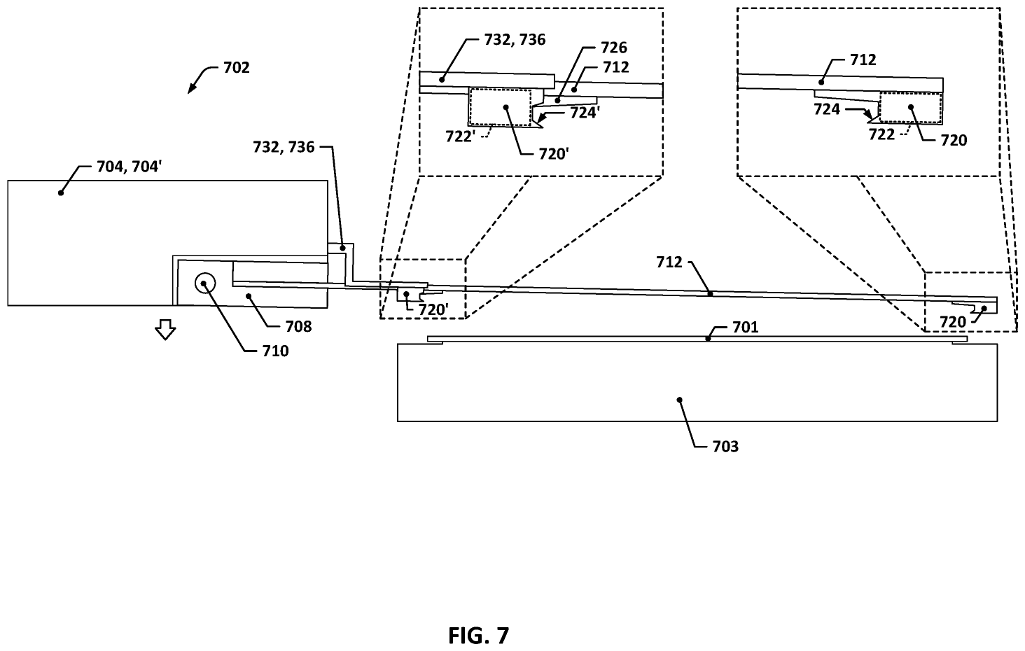

As discussed earlier, the end effector blades 112 and 114 attached to the end effector wrist unit 102 may be used to pick up a wafer 101 that is placed on a pedestal. FIGS. 7 through 11 depict side views of an example end effector wrist unit and end effector blades during various stages of a wafer pick operation.

In FIG. 7, an end effector wrist unit 702 is shown having a wrist unit housing 704, 704′ with a first end effector mount 708 and a first end effector blade 712 attached thereto. The first end effector mount 708 is rotatably mounted with respect to the wrist unit housing 704, 704′ via a rotational interface 710. The first end effector blade 712 may have a distal cleat 720 that is attached to a distal end thereof (there may be second end effector blade with another distal cleat 720 attached thereto, as in the example of FIG. 7). The distal cleat 720 may have a riser portion 722 and a catch surface 724 extending therefrom towards the wrist unit housing 704, 704′. The catch surface 724 may be spaced apart from the first end effector blade by at least a first gap distance, e.g., at least a distance greater than the thickness of the wafer 701, and may be sloped such that the first gap distance increases for each catch surface 724 with increasing distance from the respective riser portion 722, e.g., such that the catch surfaces 724 (and the catch surface 724′ discussed below, for that matter) all have normals that face towards the end effector blades and also towards the general center of the wafer 701 when the wafer 701 is held by the end effector. The wrist unit housing 704, 704′ may also contain an actuator mechanism 732 with a first portion (not shown) that is fixed with respect to the wrist unit housing 704, 704′ and a second portion 736 that is movable with respect to the first portion. The second portion 736 of the actuator mechanism 732 may have a proximal cleat 720′ with a catch surface 724′ that extends outward from a riser portion 722′ and towards the distal cleat 720. When the actuator mechanism 732 is actuated, the second portion 736 thereof may, along with the proximal cleat 720′, extend or retract towards or from the distal cleat(s) 720. The use of sloped catch surfaces 724 and 724′ may be adopted to ensure that the wafer does not contact the cleats 720 and 720′ except along the outer diameter and/or outer edges, i.e., to prevent the cleats 720 and 720′ from contacting the bottom surface of the wafer except along the bottom edge.

As shown in FIG. 7, the first end effector blade 712 has been positioned above a wafer 701 housed on a pedestal 703, e.g., a pedestal that may be within a semiconductor processing chamber. The pedestal 703 may provide a recess or recesses around the circumference of the wafer 701 over which the wafer 701 may overhang.

During a wafer pick operation, the end effector wrist unit 702 may be caused to be lowered towards the pedestal 703 and the wafer 701. The first end effector blade 712 may, due to the weight of gravity, have rotated downward until it reaches a limit of an angular range in which it is configured to be rotatable within.

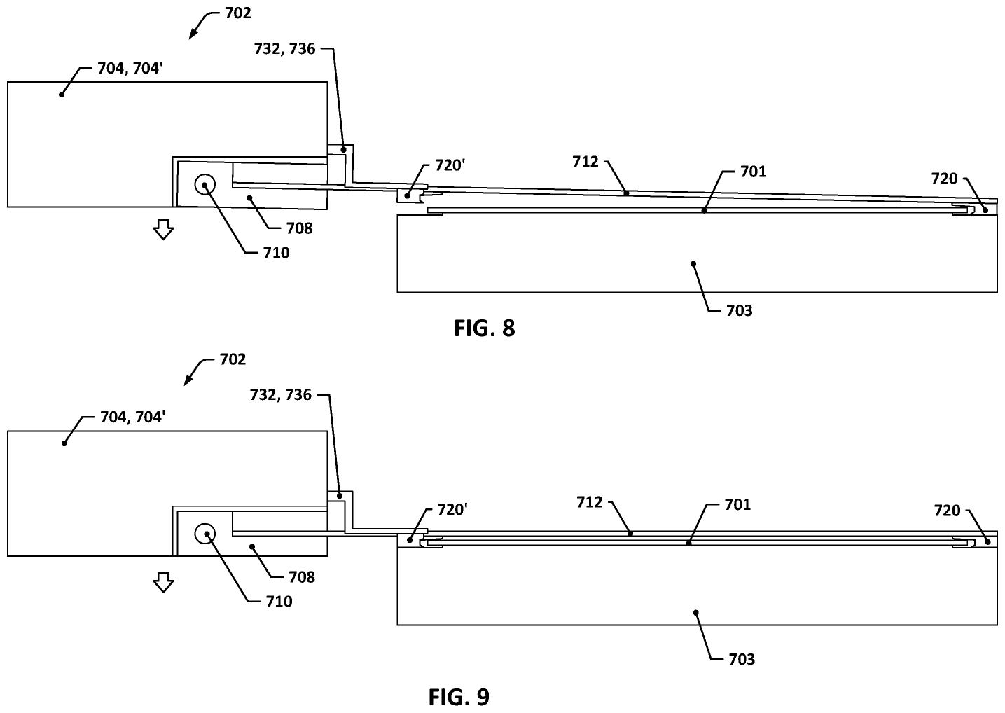

In FIG. 8, the end effector wrist unit 702 has been caused to be lowered further until the distal cleat 720 has come into contact with the pedestal 703. In FIG. 9, the end effector wrist unit 702 has been caused to continue its downward movement relative to the pedestal 703 until the proximal cleat 720′ is located at an elevation that aligns with the wafer 701, e.g., such that the catch surface 724′ is below, or at least somewhat below, the bottom edge of the wafer 701. It will be appreciated that the distal cleats 720 and the proximal cleat 720′ are positioned in this configuration such that the contact surfaces 724 and 724′ thereof are all able to be entirely outside of a circle having a diameter of the wafer 701.

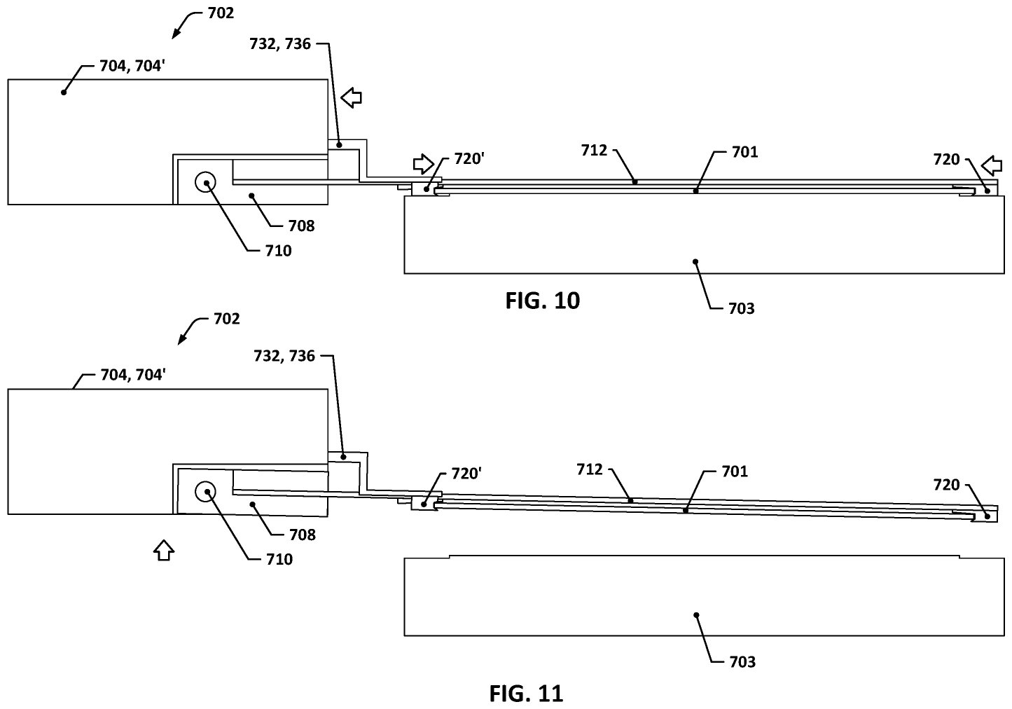

In FIG. 10, the actuator mechanism 732 may be actuated so as to cause the proximal cleat 720′ to move towards the distal cleat 720, thereby causing the catch surface 724′ to pass underneath the bottom edge of the wafer 701. At the same time, the end effector wrist unit 702 may be caused to move in the opposite direction by a lesser amount such that the distal cleat 720 is similarly caused to move towards the proximal cleat 720′ such that the catch surface 724 also passes underneath the bottom edge of the wafer 701. Such movement of the distal cleat 720 and the proximal cleat 720′ may continue until, for example, the wafer 701 is unable to potentially shift and escape the catch surfaces 724 and 724′ and the riser portions 722 and 722′. In such a configuration, the catch surfaces 724 and 724′ may all overlap a circle that is of the same diameter as the wafer 701. Such circles, which may be referred to herein as reference circles, may have a diameter that is the same as the wafer 701 that is to be handled by the end effector, e.g., 200 mm, 300 mm, 450 mm, etc.

Once the wafer 701 is securely caged by the catch surfaces 724 and 724′ and the riser portions 722 and 722′, the end effector wrist unit 702 may be caused to move upward, lifting the wafer 701 clear of the pedestal 703, supported by the catch surfaces 724 and 724′.

When the end effector wrist unit 702 is then rotated by 180°, e.g., flipped upside down, the wafer 701 may come to rest on the surfaces of the distal cleats 720 that face towards the catch surfaces 724 and on the contact pads 726. This allows the wafer 701 to be flipped upside down in between wafer pick and place operations.

When the wafer 701 is suspended beneath the end effector blade(s) 712, i.e., resting on the catch surfaces 724, the end effector wrist unit 702 may, in some implementations, be used to place the wafer on a pedestal (or on another structure). For example, the end effector wrist unit 702 may first be positioned such that the end effector blade 712 is generally parallel to the surface that will ultimately receive the wafer 701 and may then be lowered until the wafer is in contact with that surface. Once the end effector wrist unit 702 has been lowered so as to place the wafer into contact with the receiving surface, the actuator mechanism 732 may be actuated to cause the proximal cleat 720′ to retract away from the wafer 701, thereby releasing one edge of the wafer 701. The end effector wrist unit 702 may then be caused to move upward and simultaneously towards the wafer 701 such that the end effector wrist unit 702 follows a sloping path, e.g., a path that slopes at 20° to 40° from horizontal, e.g., 30° from horizontal. Such movement allows the proximal cleat 720′ (assuming it has been retracted sufficiently) to clear the wafer edge while also allowing the catch surfaces of the distal cleats 720 to move out from underneath the wafer 701. The end effector wrist unit 702 may then be moved vertically upward once the cleats 720 and 720′ have been moved clear of the wafer 701. A similar process but with the direction of vertical movement reversed may be performed to place the wafer 701 in a location when the end effector wrist unit 702 is rotated 180°, i.e., with the wafer 701 above the end effector blade 712.

Alternatively, the same process discussed above with respect to FIGS. 7 through 11 may generally be performed in reverse to perform a wafer placement operation (in either orientation of the end effector wrist unit 702).

It will be appreciated that the end effector wrist units discussed herein provide for only a very limited amount of rotational movement of the end effector mount assembly and the end effector blades mounted thereto relative to the wrist unit housing, and that such movement may be passive in nature, e.g., not subject to control by way of a motor, actuator, or spring mechanism. For example, in the event that rotational flexure bearings are used by for the rotational interface(s) in the end effector wrist unit, the torque developed by such flexure bearings when flexed may be insufficient to prevent the end effector mount assembly and the end effector blades mounted thereto from rotating through the angular range of motion defined by the first rotational limit and the second rotational limit due to gravitational loading of the end effector mount assembly and the end effector blades when the end effector wrist unit is oriented such that the major surfaces of the end effector blades are generally horizontal (subject to the slight slope that may develop when at the first rotational limit or the second rotational limit) or flipped upside down from such an orientation. Thus, the end effector blades attached to such end effector wrist units may be free to have a small amount of compliance that allows them to engage with a pedestal during wafer pick operations, as shown in FIGS. 7 through 11. The damper mechanism may optionally be used to limit the speed with which the end effector mount assembly rotates relative to the wrist unit housing and to damp out any shocks or vibration that may occur as a result of such rotational movement.

It will also be appreciated that the end effector wrist units discussed herein may not only be used to pick and place wafers from horizontal locations, but also from wafer locations in which the wafers may be placed on or picked from wafer support surfaces that are non-horizontal, e.g., at angles of up to 60° from horizontal.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

Terms such as “about,” “approximately,” “substantially,” “nominal,” or the like, when used in reference to quantities or similar quantifiable properties, are to be understood to be inclusive of values within +10% of the values or relationship specified (as well as inclusive of the actual values or relationship specified), unless otherwise indicated.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
an end effector wrist unit, the end effector wrist unit including:
a wrist unit housing;
an end effector mount assembly having a first end effector mount; and
one or more rotational interfaces, wherein:
the first end effector mount is configured to mechanically connect with a first end effector blade having a major surface defining a first plane,
the end effector mount assembly is connected with the wrist unit housing via the one or more rotational interfaces such that the end effector mount assembly is rotatable through a first angular range of motion relative to the wrist unit housing and about a first axis, and
the first axis is substantially parallel to the first plane when the first end effector is mounted to the first end effector mount.

2. The apparatus of claim 1, wherein the first end effector mount has a first planar end effector mounting surface that is configured to mate against the first end effector blade when the first end effector mount is mated to the first end effector blade and the first planar end effector mounting surface is parallel to the first axis.

3. The apparatus of claim 1, further comprising the first end effector blade.

4. The apparatus of claim 1, further comprising a first positive stop and a second positive stop, the first positive stop positioned so as to contact a portion of the end effector mount assembly when the end effector mount assembly is at a first rotational limit of the first angular range of motion and the second positive stop positioned so as to contact a portion of the end effector mount assembly when the end effector mount assembly is at a second rotational limit of the first angular range of motion.

5. The apparatus of claim 4, wherein one or both of the first positive stop and the second positive stop are adjustable.

6. The apparatus of claim 1, wherein the first angular range of motion is less than 10 degrees.

7. The apparatus of claim 1, further comprising a damper mechanism that is configured to damp rotational movement of the end effector mount assembly relative to the wrist unit housing.

8. The apparatus of claim 7, further comprising a draw link and a rocker arm, wherein:
the draw link has a first end rotatably coupled to a first end of the rocker arm so as to be rotatable about a second axis relative to the rocker arm and a second end rotatably coupled to the end effector mount assembly so as to be rotatable about a third axis relative to the end effector mount assembly, and
the rocker arm has a second end rotatably coupled with a first end of the damper mechanism so as to be rotatable about a fourth axis relative to the damper mechanism and is mounted so as to be rotatable about a fifth axis that is fixed with respect to the wrist unit housing.

9. The apparatus of claim 8, wherein a first distance between the fifth axis and the fourth axis is greater than a second distance between the fifth axis and the second axis.

10. The apparatus of claim 9, wherein the first distance is at least 1.5 times the second distance.

11. The apparatus of claim 3, further comprising a second end effector blade that is fixed with respect to the end effector mount assembly.

12. The apparatus of claim 11, wherein:
the first and second end effector blades each have corresponding distal ends and corresponding proximal ends,
the proximal ends of the first and second end effector blades are fixedly mounted to the end effector mount assembly,
the distal ends of the first and second end effector blades each have a corresponding distal cleat mounted thereto,
each distal cleat has riser portion extending away from the corresponding end effector blade and a catch surface extending outward from the riser portion thereof, and
each catch surface is spaced apart from the corresponding end effector blade by at least a first gap distance.

13. The apparatus of claim 12, wherein each catch surface slopes away from the corresponding end effector blade with increasing distance from the riser portion from which that catch surface extends.

14. The apparatus of claim 13, further comprising an actuator mechanism and a proximal cleat, wherein:
the actuator mechanism has a first portion and a second portion,
the first portion of the actuator mechanism is fixed with respect to the end effector mount assembly,
the second portion of the actuator mechanism is configured to be movable between a first configuration and a second configuration relative to the first portion of the actuator mechanism,
the proximal cleat is fixed with respect to the second portion of the actuator mechanism and has a catch surface that faces in substantially the same direction as the catch surfaces of the distal cleats,
the catch surface of the proximal cleat and the catch surfaces of the distal cleats, in the first configuration, do not overlap a first reference circle when the second portion of the actuator mechanism is in the first configuration,
the catch surface of the proximal cleat and the catch surfaces of the distal cleats, in the second configuration, all overlap a second reference circle when the second portion of the actuator mechanism is in the second configuration, and
the first reference circle and the second reference circle have the same diameter.

15. The apparatus of claim 14, wherein the first reference circle has a diameter selected from the group consisting of 200 mm, 300 mm, and 450 mm.

16. The apparatus of claim 1, wherein the end effector wrist unit is configured such that:
when the end effector wrist unit is positioned in a first orientation with the first axis horizontal and the first plane substantially horizontal, the end effector mount assembly moves to the first rotational limit of the first angular range of motion due solely to gravitational loading, and
when the end effector wrist unit is positioned in a second orientation opposite the first orientation, the end effector mount assembly also moves to the second rotational limit of the first angular range of motion due solely to gravitational loading.

17. The apparatus of claim 3, wherein the first end effector blade is made of a ceramic material.

18. The apparatus of claim 17, wherein the first end effector blade is made of silicon carbide.

19. The apparatus of claim 18, further comprising a base, one or more robot arm links, and a wrist drive unit, wherein:
the one or more robot arm links include a first robot arm link that is configured to be rotatable relative to the base and about a base axis,
the wrist drive unit is supported by the one or more robot arm links and includes a wrist mount that is rotatable about an axis that is perpendicular to an axis that is parallel to the base axis, and
the end effector wrist unit is mounted to the wrist mount.

20. The apparatus of claim 18, further comprising a base, one or more robot arm links, and a wrist drive unit, wherein:
the one or more robot arm links include a first robot arm link that is configured to be rotatable relative to the base,
the wrist drive unit is supported by the one or more robot arm links and includes a wrist mount that is rotatable about an axis that is perpendicular to the first axis, and
the end effector wrist unit is mounted to the wrist mount.

21-25. (canceled)
